(19) United States
(12) Patent Application Publication
(10) Pub. No.: US 2005/0007842 A1
(43) Pub. Date: Jan. 13, 2005

(54) Amplifying circuit, amplifying apparatus, and memory apparatus

(75) Inventor: Katsuya Nakashima, Nagasaki (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation

(21) Appl. No.: 10/883,882

(22) Filed: Jul. 2, 2004

(30) Foreign Application Priority Data
Jul. 11, 2003 (JP) P2003-273646

(51) Int. Cl. G11C 7/00

(52) U.S. Cl. 365/200

(57) ABSTRACT

The present invention is proposed to attain the higher speed and lower electric power consumption in an amplifying circuit, wherein the amplifying circuit comprises a differential type amplifying circuit, a latch type amplifying circuit, and a switching circuit for switching the differential type amplifying circuit and the latch type amplifying circuit. In this configuration, the differential type amplifying circuit and the latch type amplifying circuit have a common load. Further in the present amplifying circuit, the switching circuit stops the operation of the differential type amplifying circuit after starting the operation of the latch type amplifying circuit.

### CROSS REFERENCE TO RELATED APPLICATION

This application claims priority from Japanese Priority Document No. 2003-273646, filed on Jul. 11, 2003 with the Japanese Patent Office, which document is hereby incorporated by reference.

### BACKGROUND OF THE INVENTION

1. Field of the Invention

The present invention relates to an amplifying circuit, amplifying apparatus, and a memory apparatus.

2. Description of Related Art

Conventionally, amplifying circuits for amplifying signals are mostly used in various circuits built in many kinds of electronic apparatuses. In particular, in a memory apparatus having a larger storage capacity, a sensing amplifier serving as the amplifying circuit is connected to each of memory cells.

As the above-mentioned amplifying circuit, a differential type amplifying circuit 101 having differentially connected two transistors Q101, Q102 as shown in FIG. 6, and also a latch type amplifying circuit 102 in which a latch is composed of four transistors Q103, Q104, Q105 and Q106 as shown in FIG. 7 are mainly and widely known (for example, refer to a Patent Document 1: Japanese Laid Open Patent Application No. JP-A-Heisei 10-3790).

Those amplifying circuits are used in electronic apparatuses in many cases. Thus, by improving the operation speed of each amplifying circuit and also by reducing the electric power consumption, it is required to design the electronic apparatus satisfying higher performance and lower electric power consumption.

By the way, for the above-mentioned conventional amplifying circuits, the following problems have been pointed out.

That is, in a differential type amplifying circuit, even if the potential difference between input signals is small, the amplifying operation can be carried out at a high speed. However, since a signal amplification factor is excessively low by the above mentioned one differential type amplifying circuit, it is recommended to increase the signal amplification factor. To do so, it is necessary to connect plural stages of the differential type amplifying circuits in series, but this may bring about the fear of the increase in the electric power consumption.

Also, in a latch type amplifying circuit, it is able to make the signal amplification factor greater by only one latch type amplifying circuit. However, in the range where the potential difference between latched input signals is minute, the input signals have to be gradually amplified, and this may bring about the fear that the amplification can not be carried out at high speed.

Accordingly, in the above-mentioned conventional amplifying circuits, it was impossible to attain both the higher speed and the lower electric power consumption. Thus, it was impossible to satisfy the requirements of the higher performance and lower electric power consumption necessary for the respective electronic apparatuses of recent years.

### SUMMARY OF THE INVENTION

A first one aspect of the present invention is to propose an amplifying circuit that comprises a differential type amplifying circuit, a latch type amplifying circuit, and a switching circuit for switching the differential type amplifying circuit and the latch type amplifying circuit, wherein the differential type amplifying circuit and the latch type amplifying circuit have a common load. In the amplifying circuit of the invention, the common load may be a resister, or may be a transistor.

A second aspect of the present invention is to propose an amplifying circuit that comprises a differential type amplifying circuit, a latch type amplifying circuit, and a switching circuit for switching the differential type amplifying circuit and the latch type amplifying circuit, wherein the latch type amplifying circuit is made into operation after the differential type amplifying circuit is made into operation by operating the switching circuit.

In the amplifying circuit of the present invention, the switching circuit stops the operation of the differential type amplifying circuit after starting the operation of the latch type amplifying circuit.

A third aspect of the present invention is to propose an amplifying apparatus that comprises a differential type amplifying circuit; a latch type amplifying circuit, and a switching circuit for switching the differential type amplifying circuit and the latch type amplifying circuit, wherein the differential type amplifying circuit and the latch type amplifying circuit have a common load. In the amplifying circuit of the above invention, the common load may be a resister, or may be a transistor.

A forth aspect of the present invention is to propose an amplifying apparatus that comprises a differential type amplifying circuit, a latch type amplifying circuit, and a switching circuit for switching said differential type amplifying circuit and said latch type amplifying circuit, wherein the latch type amplifying circuit is made into operation after the differential type amplifying circuit is made into operation by operating this switching circuit.

In the amplifying apparatus of the present invention, the switching circuit stops the operation of the differential type amplifying circuit after starting the operation of the latch type amplifying circuit.

A fifth aspect of the present invention is to propose a memory apparatus having memory cells connected to sensing amplifiers, in which the sensing amplifier includes a differential type amplifying circuit, a latch type amplifying circuit, and a switching circuit for switching the differential type amplifying circuit and the latch type amplifying circuit, wherein the differential type amplifying circuit and the latch type amplifying circuit have a common load. In the memory apparatus of the above invention, the common load may be a resister, or may be a transistor.

A sixth aspect of the present invention is to propose a memory apparatus having memory cells connected to sensing amplifiers, in which the sensing amplifier includes a differential type amplifying circuit, a latch type amplifying circuit, and a switching circuit for switching the differential type amplifying circuit and the latch type amplifying circuit, wherein the latch type amplifying circuit is made into operation after the differential type amplifying circuit is made into operation by operating this switching circuit.

In the memory apparatus of the present invention, the switching circuit stops the operation of the differential type amplifying circuit after starting the operation of the latch type amplifying circuit.

A memory apparatus according to the present invention is designed such that the memory apparatus has a memory area composed of a plurality of memory cells and complementarily stores memory data of one bit by using a pair of memory cells. When the memory data is read out, the output is obtained after amplifying a content stored in the pair of memory cells by using a sensing amplifier.

And, the present invention has the feature in the configuration of the sensing amplifier that is an amplifying circuit.

That is, the amplifying circuit according to the present invention is designed so as to have a differential type amplifying circuit that uses transistors serving as a differential pair, a latch type amplifying circuit that uses a pair of transistors constituting a latch, and also a switching circuit for switching the operation of those two amplifying circuits.

And, it is designed such that, after the switching circuit is applied to operate the differential type amplifying circuit, the latch type amplifying circuit goes into operation, and an input signal is firstly amplified by the differential type amplifying circuit, and then the input signal amplified by the differential type amplifying circuit is further amplified by the latch type amplifying circuit.

In particular, the present invention is designed so as to stop the operation of the differential type amplifying circuit after starting the operation of the latch type amplifying circuit by using the switching circuit.

In this way, after the switching circuit is made the differential type amplifying circuit into operation, the latch type amplifying circuit is made to go into operation. Consequently, the input signal is amplified by the differential type amplifying circuit, at first and then amplified by the latch type amplifying circuit. Thus, by making the efficient use of only the excellent properties of the differential type amplifying circuit and the latch type amplifying circuit, it is possible to attain feature of both higher speed and lower electric power consumption of the amplifying circuit.

That is, as mentioned above, the differential type amplifying circuit has the property that even if the potential difference between the input signals is small, the amplification can be carried out at the high speed. On the other hand, the latch type amplifying circuit has the property that if there is the potential difference of a certain degree between the input signals, the amplification can be carried out at the high speed, and only the single circuit can make the signal amplification factor greater.

Thus, if the potential difference between the input signals immediately after the start of amplifying operation is small, the differential type amplifying circuit is applied to carry out the amplifying operation, and if the potential difference of a certain degree is generated between the input signals, the latch type amplifying circuit is activated to carry out the amplifying operation. Consequently, it is possible to reduce the time and power which are necessary for the amplifying operation, and possible to simultaneously attain higher speed and lower electric power consumption of the amplifying circuit.

Consequently, it is possible to attain higher speed and lower electric power consumption of the memory device including this amplifying circuit, the various signal processing apparatuses, and the memory device, and is also possible to correspond to the requests of higher performance and lower electric power consumption of the respective electronic apparatuses of recent years.

Moreover, if the operation of the differential type amplifying circuit is stopped before the latch type amplifying circuit is operated, the potential of the signal amplified by the differential type amplifying circuit is reduced by discharge. Correspondingly, the time and labor which are necessary for the amplification is excessively consumed by this discharged amount. However, by stopping the operation of the differential type amplifying circuit after starting the operation of the latch type amplifying circuit, it is able to prevent the reduction in the signal amplified by the differential type amplifying circuit, and also is able to perform higher speed and lower electric power consumption of the amplifying circuit more and more.

That is, according to the present invention, after the switching circuit makes to operate the differential type amplifying circuit, the latch type amplifying circuit is operated, which enables the achievements of higher speed and lower electric power consumption of the amplifying circuit.

In particular, if it is designed to stop the operation of the differential type amplifying circuit after starting the operation of the latch type amplifying circuit, it is possible to prevent the drop in the signal amplified by the differential type amplifying circuit, and is possible to attain higher speed and lower electric power consumption of the amplifying circuit more and more.

### BRIEF DESCRIPTION OF THE DRAWINGS

FIG. 1 is a circuit diagram showing an amplifying circuit according to the present invention;

FIG. 2 is a timing chart showing the timing of a switching signal;

FIG. 3 is a circuit diagram showing another amplifying circuit;

FIG. 4 is a circuit diagram showing another amplifying circuit;

FIG. 5 is a circuit diagram showing another amplifying circuit;

FIG. 6 is a circuit diagram showing a conventional amplifying circuit, and

FIG. 7 is a circuit diagram showing another conventional amplifying circuit.

### DESCRIPTION OF THE PREFERRED EMBODIMENT

The specific embodiments of the amplifying circuit according to the present invention will be described below with reference to the drawings. By the way, an amplifying circuit according to the present invention can be applied to a sensing amplifier of a memory device, and can be applied even to amplifying circuits of the other various signal processing apparatuses.

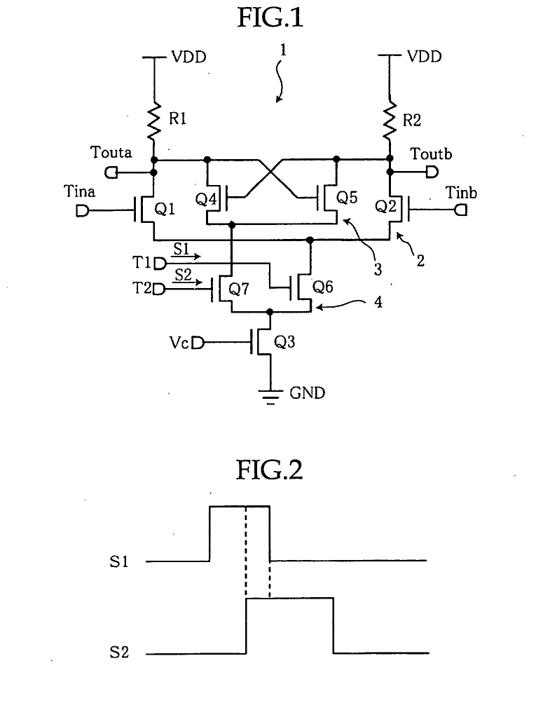

An amplifying circuit 1 according to the present invention is provided with a differential type amplifying circuit 2, a latch type amplifying circuit 3, and a switching circuit 4 for switching the operation between those two amplifying circuits 2, 3, as shown in FIG. 1.

The differential type amplifying circuit 2 is composed of N-channel MOS-type transistors (FETs) Q1, Q2 serving as a differential pair, a pair of resistors R1, R2 serving as a load, and an N-channel MOS-type transistor (FET) Q3 serving as a constant current source.

Specifically, in the differential type amplifying circuit 2, each one of terminals of the resistors R1, R2 are connected to a power source terminal VDD, drain terminals of the transistors Q1, Q2 are connected to each of the other terminals of those resistors R1, R2, and input terminals Tina, Tinb are connected to gate terminals of those transistors Q1, Q2. Moreover, a drain terminal of the transistor Q3 is connected through the switching circuit 4 to source terminals of the transistors Q1, Q2, a source terminal of this transistor Q3 is connected to a ground terminal GND, and a predetermined voltage Vc is applied to a gate terminal of this transistor Q3.

Also, the latch type amplifying circuit 3 is composed of a pair of N-channel MOS-type transistors (FETs) Q4, Q5 constituting a latch, the pair of resistors R1, R2, the N-channel MOS-type transistor (FET) Q3 serving as the constant current source. Here, the resistors R1, R2 and the transistor Q3 are commonly used common to the above-mentioned differential type amplifying circuit 2 and the latch type amplifying circuit 3. That is, the resistors R1, R2 are a common load.

more specifically, in the latch type amplifying circuit 3, each one of the terminals of the resistors R1, R2 are connected to the power source terminal VDD, drain terminals of the transistors Q4, Q5 are connected to each of the other terminals of those resistors R1, R2, and source terminals and gate terminals of those transistors Q4, Q5 are connected as depicted in FIG. 1. Moreover, the drain terminal of the transistor Q3 is connected through the switching circuit 4 to the source terminals of the transistors Q4, Q5, the source terminal of this transistor Q3 is connected to the ground terminal GND, and the predetermined voltage Vc is applied to the gate terminal of this transistor Q3.

Also, in the latch type amplifying circuit 3, output terminals Touta, Toutb are connected to the drain terminals of the transistors Q4, Q5. The gate terminals of the other transistors Q4, Q5 are connected to the drain terminals of those transistors Q4, Q5, and the drain terminals of the transistors Q1, Q2 of the differential type amplifying circuit 2 are connected.

The switching circuit 4 is composed of two N-channel MOS-type switching transistors (FETs) Q6, Q7. The switching transistor Q6 controls the operation of the differential type amplifying circuit 2. On the other hand, the switching transistor Q7 controls the operation of the latch type amplifying circuit 3.

More specifically, in the switching circuit 4, a drain terminal of the switching transistor Q6 is connected to the source terminals of the transistors Q1, Q2 of the differential type amplifying circuit 2, a source terminal of this switching transistor Q6 is connected to the drain terminal of the transistor Q3, and a switch terminal T1 for inputting a switching signal S1 is connected to the gate terminal of the switching transistor Q6.

Also, in the switching circuit 4, a drain terminal of the switching transistor Q7 is connected to the source terminals of the transistors Q4, Q5 of the latch type amplifying circuit 3, a source terminal of this switching transistor Q7 is connected to the drain terminal of the transistor Q3, and a switch terminal T2 for inputting a switching signal S2 is connected to the gate terminal of the switching transistor Q7.

The amplifying circuit 1 is configured as explained above, and designed so as to carry out the amplifying operation which will be explained below.

That is, the amplifying circuit 1 is applied with input signals to be amplified, at the input terminals Tina, Tinb, respectively, and is supplied with switching signals S1, S2 at the switching terminals T1, T2 at timings shown in FIG. 2.

And, in the amplifying circuit 1, the differential type amplifying circuit 2 starts to operate simultaneously with rising of the switching signal S1, and amplifies the potential difference between the input signals supplied to the input terminals Tina, Tinb.

After that, in the amplifying circuit 1, the latch type amplifying circuit 3 starts to operate simultaneously with rising of the switching signal S2. Consequently, the signal amplified by the differential type amplifying circuit 2 is latched by the transistors Q4, Q5 of the latch type amplifying circuit 3, and continuously amplified by the latch type amplifying circuit 3 until the switching signal S2 is fallen.

The differential type amplifying circuit 2 starts its operation simultaneously with the rising of the switching signal S1, and stops its operation simultaneously with falling of the switching signal S1, after the elapse of a predetermined time from the rising of the switching signal S2.

In this way, in the amplifying circuit 1, at first, the differential type amplifying circuit 2 starts to amplify the input signals, in which the potential difference is small, at the high speed until a potential difference of the certain degree is generated. After that, the latch type amplifying circuit 3 carries out the amplifying operation at high speed and with high amplification factor.

Consequently, the amplifying circuit 1 reduces the time and electric power, which are necessary for the amplifying operation, and attains higher speed and lower electric power consumption.

Moreover, the amplifying circuit 1 stops the operation of the differential type amplifying circuit 2 after stating the operation of the latch type amplifying circuit 3, and consequently prevents the drop in the signal amplified by the differential type amplifying circuit 2, thereby attaining higher speed and lower electric power consumption of the amplifying circuit 1 more and more.

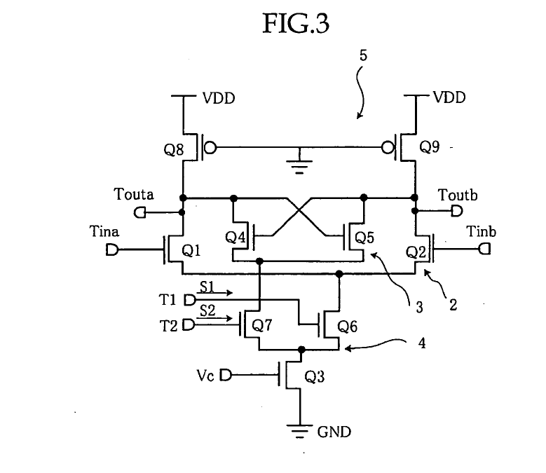

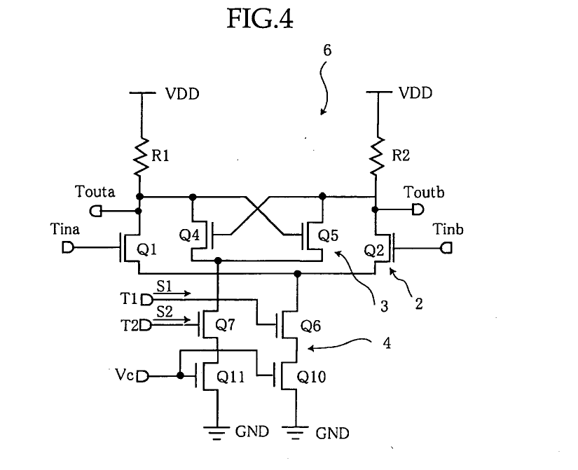

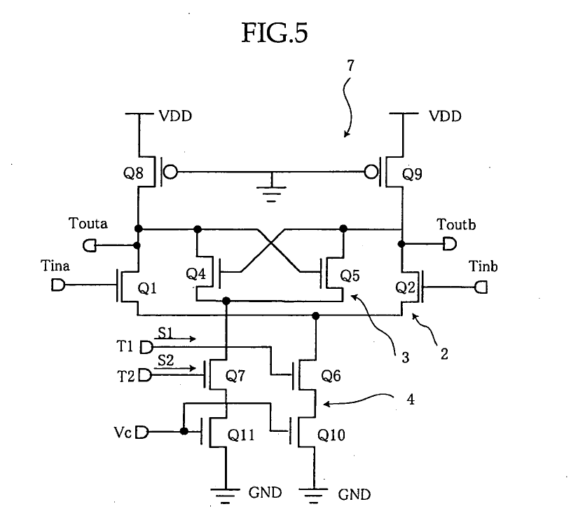

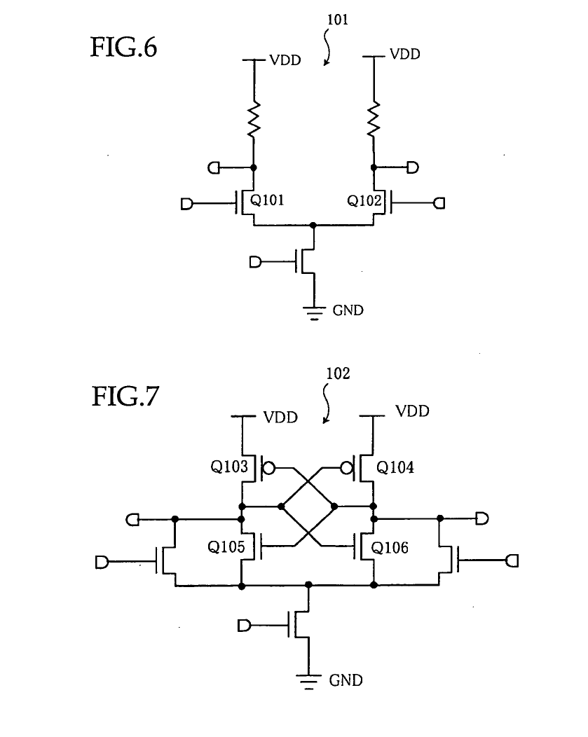

The amplifying circuit 1 according to the present invention is not limited to the circuit as explained above. That is, such as an amplifying circuit 5 shown in FIG. 3, instead of the resistors R1, R2 serving as the common load, transistors (FETs) Q8, Q9 that are always set at conductive states may be used as the common load. Also, such as an amplifying circuit 6 shown in FIG. 4, transistors (FETs) Q10, Q11 serving as the constant current sources may be installed in the differential type amplifying circuit 2 and the latch type amplifying circuit 3, respectively. Also, such as an amplifying circuit 7, as shown in FIG. 5, the circuits shown in FIG. 3 and FIG. 4 may be combined.

1. An amplifying circuit comprising:
a differential type amplifying circuit;
a latch type amplifying circuit; and
a switching circuit for switching said differential type amplifying circuit and said latch type amplifying circuit, wherein;
said differential type amplifying circuit and said latch type amplifying circuit have a common load.

2. The amplifying circuit as cited in claim 1, wherein;
said common load is a resister.

3. The amplifying circuit as cited in claim 1, wherein;
said common load is a transistor.

4. An amplifying circuit comprising:
a differential type amplifying circuit;
a latch type amplifying circuit; and
a switching circuit for switching said differential type amplifying circuit and said latch type amplifying circuit, wherein;
said latch type amplifying circuit is made in operation after said differential type amplifying circuit is made in operation by operating this switching circuit.

5. The amplifying circuit as cited in claim 4, wherein;
said switching circuit stops the operation of said differential type amplifying circuit after starting the operation of the latch type amplifying circuit.

6. An amplifying apparatus comprising:
a differential type amplifying circuit;
a latch type amplifying circuit; and
a switching circuit for switching said differential type amplifying circuit and said latch type amplifying circuit, wherein;
said differential type amplifying circuit and said latch type amplifying circuit have a common load.

7. The amplifying apparatus as cited in claim 6, wherein;
said common load is a resister.

8. The amplifying apparatus as cited in claim 6, wherein;
said common load is a transistor.

9. An amplifying apparatus comprising:
a differential type amplifying circuit;
a latch type amplifying circuit; and
a switching circuit for switching said differential type amplifying circuit and said latch type amplifying circuit, wherein;
said latch type amplifying circuit is made in operation after said differential type amplifying circuit is made in operation by operating this switching circuit.

10. The amplifying apparatus as cited in claim 9, wherein;
said switching circuit stops the operation of said differential type amplifying circuit after starting the operation of the latch type amplifying circuit.

11. A memory apparatus having memory cells connected to sensing amplifiers, wherein;
said sensing amplifier includes;
a differential type amplifying circuit;
a latch type amplifying circuit; and
a switching circuit for switching said differential type amplifying circuit and said latch type amplifying circuit, wherein;
said differential type amplifying circuit and said latch type amplifying circuit have a common load.

12. The memory apparatus as cited in claim 11, wherein;
said common load is a resister.

13. The memory apparatus as cited in claim 11, wherein;
said common load is a transistor.

14. A memory apparatus having memory cells connected to sensing amplifiers, wherein;
said sensing amplifier includes;
a differential type amplifying circuit;
a latch type amplifying circuit; and
a switching circuit for switching said differential type amplifying circuit and said latch type amplifying circuit, wherein;
said latch type amplifying circuit is made in operation after said differential type amplifying circuit is made in operation by operating this switching circuit.

15. The memory apparatus as cited in claim 14, wherein;
said switching circuit stops the operation of said differential type amplifying circuit after starting the operation of the latch type amplifying circuit.
